(19) United States
(12) Patent Application Publication
(10) Pub. No.: US 2023/0129777 A1
(43) Pub. Date: Apr. 27, 2023

(54) Laser Deposition with a Reactive Gas

(71) Applicant: The United States of America, as represented by the Secretary of the Navy, San Diego, CA (US)

(72) Inventors: Alexandru Hening, San Diego, CA (US); Maria Dinescu, Bucharest (RO); Wayne C. McGinnis, San Diego, CA (US); Ryan P. Lu, San Diego, CA (US)

(21) Appl. No.: 17/507,675

(22) Filed: Oct. 21, 2021

(51) Int. Cl. C23C 14/00; C23C 14/52; C23C 14/54

(52) U.S. Cl. CPC C23C 14/0036; C23C 14/52; C23C 14/541

(57) ABSTRACT

An apparatus for laser deposition with a reactive gas includes a source, a target, and a substrate. The source emits a plasma jet of the reactive gas. The target generates a plasma plume of a deposition material when a laser beam ablates the target. The substrate collects a film resulting from a chemical reaction between the deposition material from the plasma plume and the reactive gas from the plasma jet. Correspondingly, a method for laser deposition with a reactive gas includes steps of emitting a plasma jet of the reactive gas, ablating a target with a laser beam, and collecting a film on a substrate. The plasma jet emits from an orifice of a source. Ablating the target generates a plasma plume of a deposition material. The film results from a chemical reaction between the deposition material from the plasma plume and the reactive gas from the plasma jet.

### FEDERALLY-SPONSORED RESEARCH AND DEVELOPMENT

The United States Government has ownership rights in this invention. Licensing and technical inquiries may be directed to the Office of Research and Technical Applications, Naval Information Warfare Center Pacific, Code 72120, San Diego, Calif., 92152; voice (619) 553-5118; ssc_pac_t2@navy.mil. Reference Navy Case Number 110267.

### BACKGROUND OF THE INVENTION

Laser deposition uses a laser beam to vaporize material and then deposit the vaporized material. However, when the desired deposit includes volatile components, such as oxygen or nitrogen, these volatile components tend to remain in a gas phase and hence not deposited. Especially problematic is when the desired deposit includes multiple volatile components with differing chemical reactivity because the volatile components with more reactivity inhibit or prevent depositing the volatile components with less reactivity. There is a general need to produce deposits with a wide variety of compositions despite such constraints.

### SUMMARY

An apparatus for laser deposition with a reactive gas includes a source, a target, and a substrate. The source emits a plasma jet of the reactive gas. The target generates a plasma plume of a deposition material when a laser beam ablates the target. The substrate collects a film resulting from a chemical reaction between the deposition material from the plasma plume and the reactive gas from the plasma jet. Correspondingly, a method for laser deposition with a reactive gas includes steps of emitting a plasma jet of the reactive gas, ablating a target with a laser beam, and collecting a film on a substrate. The plasma jet emits from an orifice of a source. Ablating the target generates a plasma plume of a deposition material. The film results from a chemical reaction between the deposition material from the plasma plume and the reactive gas from the plasma jet.

### BRIEF DESCRIPTION OF THE DRAWINGS

Throughout the several views, like elements are referenced using like references. The elements in the figures are not drawn to scale and some dimensions are exaggerated for clarity.

FIG. 1 is a block diagram of an apparatus for laser deposition with a reactive gas, in accordance with an embodiment of the invention.

FIG. 2 is a flow diagram of a process for laser deposition with a reactive gas in accordance with an embodiment of the invention.

### DETAILED DESCRIPTION OF EMBODIMENTS

The disclosed systems and methods below may be described generally, as well as in terms of specific examples and/or specific embodiments. For instances where references are made to detailed examples and/or embodiments, it should be appreciated that any of the underlying principles described are not to be limited to a single embodiment, but may be expanded for use with any of the other methods and systems described herein as will be understood by one of ordinary skill in the art unless otherwise stated specifically.

The inventors were motivated by the recent theoretical prediction of a new class of perovskites, the oxynitrides AB(ON)₃, where A and B are metal elements, O is oxygen, and N is nitrogen. These oxynitride perovskites are predicted to have enhanced dielectric and ferroelectric properties over oxide perovskites ABO₃. Predicted applications for these perovskites include clean and renewable energy production. As compared with oxide perovskites ABO₃, the oxynitride perovskites AB(ON)₃ or ABO₂N enable a significant enrichment of possible combinations of cations not previously achievable. Recently, attempted fabrications and evaluations of such oxynitride perovskites were inconclusive because either the perovskite structure or the enhanced properties were not seen. High electronic flexibility and colossal magnetoresistance have been discovered in the EuNbO₂N and EuW(ON)₃ oxynitrides, but the HR-TEM analysis revealed a random distribution of a tetragonal superstructure in the bulk, suggesting the overall structure was not a perovskite. Enhanced dielectric properties have been seen for SrTaO₂N bulk material, but the ferroelectric behavior did not match the predictions of enhanced ferroelectric properties.

Thus, the inventors were motivated to fabricate and evaluate this new class of perovskites, the oxynitrides AB(ON)₃ or ABO₂N. However, laser deposition is difficult because some of the volatile oxygen and nitrogen forms an atmosphere surrounding the growing film, and oxygen from this atmosphere displaces the nitrogen already incorporated within the growing deposit, ejecting the displaced nitrogen into the surrounding atmosphere. This impedes achieving the desired stoichiometry for some oxynitrides, and this prevents achieving the desired stoichiometry for many oxynitrides.

The inventors have discovered that proper control of the stoichiometry is achieved when the reactivity of oxygen and nitrogen is increased by supplying excited and ionized species of oxygen and nitrogen during pulsed laser deposition. Pulsed laser deposition is augmented with a radiofrequency plasma source that generates a plasma jet supplying excited and ionized gas species during pulsed laser deposition. The radiofrequency plasma source can be mounted outside the deposition chamber with minimal impact on the deposition geometry. The radiofrequency plasma source works with gas mixtures over all pressure ranges from near vacuum to atmospheric pressure. Example gas mixtures include mixtures of argon, oxygen, and/or nitrogen. The radiofrequency discharge of the plasma source excites and ionizes the supplied gas mixture, and then the radiofrequency discharge produces a directional plasma jet that delivers the excited and ionized gas species to the deposition site. When the plasma source is operated continuously before and during pulsed laser deposition, an atmosphere of excited and ionized gas species develops surrounding the deposition site. This change from a relatively inert to a reactive atmosphere helps provide wide-ranging control of the stoichiometry because the deposition surface is exposed to the reactive atmosphere during all film formation stages, including the early stage before deposition stabilization. In particular, highly reactive nitrogen species in excited states (N, N*, N₂*) and ionized states (N+, N₂+) are present and become incorporated during deposition along with the species ablated from the target.

The addition of a radiofrequency plasma source to pulsed laser deposition enables controlling characteristics of the deposited film beyond stoichiometry. For example, because the reactive gas species have a higher sticking coefficient upon striking the growing film, a layer-by-layer film growth is favored, and this enables control of the deposited crystalline phases and their orientation. The excited and ionized species at the growth interface reduce vacancy defects in the deposited film. Due to the supplemental energy of the excited and ionized species, the deposition temperature can be reduced to lower the risk of deterioration during deposition. Thus, the increased flexibility and range of deposition conditions leads to the realization of new materials with outstanding properties, including oxynitride perovskites and more.

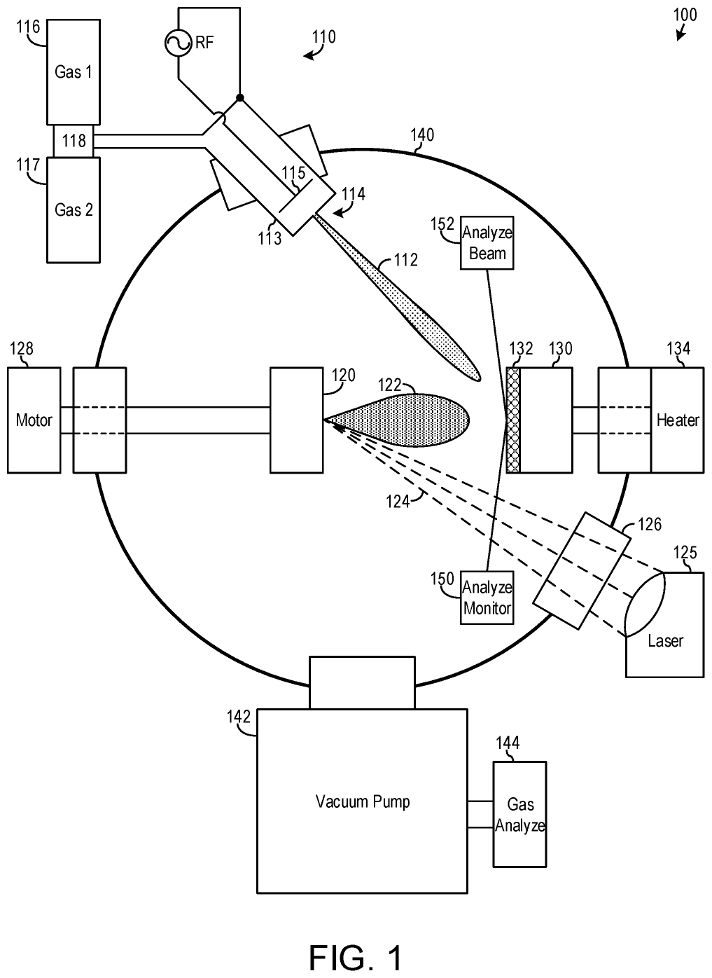

FIG. 1 is a block diagram of an apparatus 100 for laser deposition with a reactive gas in accordance with an embodiment of the invention. The apparatus 100 includes a source 110 of the reactive gas, a target 120, and a substrate 130 for collecting the film 132.

The source 110 emits a plasma jet 112 of the reactive gas. The target 120 generates a plasma plume 122 of a deposition material when a laser beam 124 ablates the target 120. The substrate 130 collects the film 132 resulting from a chemical reaction between the deposition material from the plasma plume 122 and the reactive gas from the plasma jet 112.

In one example, the apparatus 100 deposits a perovskite thin film with the stoichiometry AB(ON)₃, where A and B are metal elements, O is oxygen, and N is nitrogen. Typically, the heavier elements are supplied from the target 120 and the lighter elements are supplied from the reactive gas, but certain elements could be supplied from either the target 120 or the reactive gas, or both. For the perovskite thin film with the stoichiometry AB(ON)₃, the target 120 supplies the metals A and B, and the plasma jet 112 of reactive gas supplies the oxygen and the nitrogen.

Typically, the target 120 has a metal composition closely matching the desired stoichiometry of the metal elements in the deposited film, but significant adjustment is necessary in an atypical situation when the metals have dramatically different vapor pressures. The target 120 is typically a disk with a diameter of 25 to 50 mm and a thickness of 5 mm. For the perovskite thin film with the stoichiometry AB(ON)₃, the molar composition of the target 120 is typically half metal A and half metal B.

In contrast, when the reactive gas contains multiple elements, the relative amounts of these elements are often significantly different from the stoichiometry of these elements in the deposited film to compensate for reactivity differences between these elements. For the perovskite thin film with the stoichiometry AB(ON)₃, even though this stoichiometry has equal molar amounts of oxygen and nitrogen, the molar rate of supplying nitrogen is typically significantly higher than the molar rate of supplying oxygen to compensate for nitrogen being less reactive than oxygen.

Without the plasma jet 112 of reactive gas, similar films can be deposited when a plasma plume similar to plasma plume 122 passes through an atmosphere between the target and the substrate. However, although such an atmosphere of oxygen O₂ and nitrogen N₂ would seem to enable depositing oxynitrides like the perovskite thin film with the stoichiometry AB(ON)₃, in practice the higher reactivity of oxygen prevents successfully depositing many oxynitrides even when the atmosphere is mostly nitrogen N₂ to compensate for nitrogen being less reactive than oxygen. Frequently, any available oxygen will displace the nitrogen already incorporated within the film.

Embodiments of the invention equalize the reactivity of reactive gases, such as oxygen and nitrogen, by supplying these reactive gases in a plasma state instead of a gaseous state. Although usually the molar rates of supplying the nitrogen and oxygen still deviate significantly from the desired stoichiometry of the film to compensate for a residual difference in reactivity, supplying reactive gases in a plasma state enables depositing a much wider variety of films, including the perovskite thin film with the stoichiometry AB(ON)₃. Embodiments of the invention monitor the stoichiometry of the film during deposition, and balance the flow rates of each reactive gas to achieve the desired stoichiometry for the film.

Supplying the reactive gas in the plasma state of plasma jet 112 provides benefits beyond enabling a wider variety of deposited films. The reactive gas in the plasma state is more reactive than the gaseous state, increasing the achievable deposition rate while reducing the vacancy defects in the film. A faster deposition rate with fewer vacancy defects is even achieved when no balancing between gases is required because the plasma jet 112 contains only a single element to deposit, for example, a metal nitride thin film.

In one embodiment, the target 120 is arranged relative to the substrate 130 so that the plasma plume 122 is incident normal to the substrate 130. The laser beam 124 evaporates, excites, and ionizes atoms and sometimes molecular fragments from the target 120 to become various excited and ionized species in the plasma plume 122. The plasma species in the plasma plume 122 diverge and have usually linear trajectories from the target 120 to the substrate 130, unless collisions occur between the plasma species and the atmosphere between the target 120 and the substrate 130.

A heater 134 heats the substrate 130, and the heater 134 includes a temperature controller for monitoring a temperature of the substrate 130 and for controlling the heater 134 so that the temperature of the film 132 matches a predetermined temperature for completing the chemical reaction between the deposition material from the plasma plume 122 and the reactive gas from the plasma jet 112.

In this embodiment, the source 110 is arranged relative to the substrate 130 so that the plasma jet 112 is incident at an angle to the substrate 130. Typically, this angle is about 45 degrees, but this angle ranges from an acute angle to an oblique angle. The density of the reactive gas is highest within the plasma jet 112 and remains high near where the plasma jet 112 impacts the film 132 on the substrate 130. However, while a portion of the reactive gas of the plasma jet 112 preferably becomes incorporated into the growing film 132, the remainder spreads out to fill the vacuum vessel 140 at a backpressure with a lower density.

The vacuum vessel 140 encloses the target 120 and the substrate 130. The vacuum vessel 140 contains the plasma plume 122 of the deposition material and the plasma jet 112 of the reactive gas. A vacuum pump 142 evacuates the vacuum vessel 140 to a desired backpressure. Because increasing the backpressure slows down the dissipation of the plasma jet 112 within the vacuum vessel 140, the backpressure is controlled in one embodiment to adjust the density of the atmosphere of reactive gas adjacent the film 132, thereby influencing the growth rate and composition of the film 132.

In one embodiment, a laser 125 is disposed outside the vacuum vessel 140, which has a window 126. The laser 125 includes an optical system that focuses the laser beam 124 at high intensity on the target 120. Thus, the laser 125 is arranged to emit the laser beam 124 that is incident on the target 120 via the window 126 for generating the plasma plume 122 of the deposition material when the laser beam 124 ablates the target 120. Typically, the laser beam 124 is incident as close to normal to the target 120 as possible while avoiding blockage from substrate 130. The laser 125 is configured to emit the laser beam 124 that is a pulsed laser beam with a pulse duration of a nanosecond duration, a picosecond duration, or a femtosecond duration. A motor 128 rotates the target 120 at few rpm and the laser beam 124 scans faster to ablate the target 120 more evenly.

The characteristics of the plasma plume 122 vary depending upon characteristics of the laser beam 124, which characteristics include the wavelength, the intensity, and the pulse duration of the laser beam 124. The generation of the plasma plume 122 begins with absorption of the photons within laser beam 124.

Each photon has a probability of absorption at the target 120. At low light intensity, the interaction between each photon of laser beam 124 and the target 120 is typically a linear interaction. For linear interactions, the probability of absorption is non-zero only for wavelengths that correspond to the energies of allowed electron transitions in the target 120. For individual atoms, the allowed electron transitions are defined by the occupied and unoccupied energy states. For bulk materials, the individual electron energy states become energy bands. Photons having sufficiently high energy can directly free an electron and ionize the atom or material. Insulators and semiconductors have a band gap with no allowed energy states, and electrons in the valence band absorb photons by excitation of the electrons from the valance band over the band gap into the conduction band on up through ionization. Metals have many electrons in the conduction band, so photons interact with only a thin surface layer with a thickness corresponding to the optical penetration depth, and electrons in the conduction band of this thin surface layer absorb photons to higher energy states within the conduction band, or beyond for ionization.

However, real materials deviate from linear interactions because real materials are non-ideal with impurities and other defects. Electron energy states for some defects lie within the band gap of an insulating or semiconducting material. This allows some absorption of photons with energies lower than the band gap energy, and enables non-linear two-photon absorption where the first photon excites an electron from the valance band to the defect energy state, and the second photon excites the electron from the defect energy state into the valance band. The probability of two-photon absorption depends on the defect density and the lifetime of the electrons in the defect energy states. In high-quality materials, such as those used in semiconductor and optical industries, the defect density is typically so low that two-photon absorption does not significantly alter the optical properties of the material. However, two-photon absorption has found many applications in high-resolution imaging and in a high-resolution three-dimensional micro-fabrication method using two-photon polymerization.

Deviations from linear interactions also occur at very high light intensities that produce non-linear interactions. Focused laser beams produce such very high light intensities. At a light intensity of approximately 10¹² W/cm², significant multi-photon absorption occurs without needing defect energy states when the first photon excites an electron from the valance band to a so-call virtual energy state with a femtosecond lifetime, and the intensity is high enough that before the electron decays from the virtual energy state with its femtosecond lifetime, a second photon excites the electron from the virtual energy state to a higher virtual energy state or into the valance band. In laser ablation, this phenomenon becomes significant with focused femtosecond laser pulses. At even higher light intensities, the electric field of the light can distort the local potential of the crystal lattice, enabling tunneling ionization.

The pulse duration of the laser beam 124 further affects ablation of the target 120. The ablation process is nearly continuous throughout nanosecond pulses, but most of the ablation process occurs after the laser pulse for femtosecond pulses. In addition, a laser pulse of a given energy has increased light intensity if the laser pulse is compressed into a shorter duration, and this increased light intensity amplifies non-linear absorption. Thus, absorption of the laser beam 124 and ablation of the target 120 depend on characteristics of the laser beam 124 including its wavelength determining each photon's energy, focusing of the laser beam 124 to increase its intensity, and the pulse duration of the laser beam 124.

For nanosecond pulses, the prevalent ablation mechanism is typically impact ionization. Seed electrons are generated by direct photon absorption when the laser beam 124 has a suitable wavelength, or through defect-assisted absorption. These seed electrons absorb further photons to become energetic free electrons that strike atoms of target 120 and release an avalanche of additional free electrons, locally vaporizing the target 120. This vaporized material forms a plasma shield that absorbs the remaining duration of the nanosecond pulse, preventing the ablation of underlying material from the target 120, but the species within the plasma plume 122 typically become ions of individual atoms without any molecular fragments. Typically, any multi-photon absorption occurs through defect energy states and not through virtual energy states. When using nanosecond pulses, a laser beam 124 with a wavelength in the ultra-violet range is usually preferred to achieve high ablation efficiency through direct photon absorption in the target 120.

For picosecond pulses, the dominant absorption mechanisms depend strongly on the material. For some materials, the mechanisms discussed below for femtosecond pulses become important. However, for most materials, the wavelength of laser beam 124 remains the most important factor because any multi-photon absorption occurs through defect energy states and not through virtual energy states.

For femtosecond pulses, multi-photon absorption becomes important, not only for generation of the seed electrons for impact ionization, but often as the dominant absorption mechanism. Tunneling ionization typically requires higher intensities than those commonly used in laser ablation, but is significant in some cases, especially for femtosecond pulses from high-wattage infrared lasers. The non-linear absorption from high light intensity makes femtosecond lasers less dependent on the laser wavelength.

The ablation process after a femtosecond laser pulse is more complicated than for a nanosecond pulse. The actual ablation takes place long after the pulse has ended and hence thermal mechanisms no longer sufficiently describe the process. Although femtosecond pulses usually imply high intensity, pump-probe experiments with low-intensity femtosecond pulses have directly imaged, with high temporal resolution, a rapid melting and desorption of atoms and molecules from non-metallic materials. A thin surface layer, with a thickness of a monolayer or a few nanometers, becomes ablated through Coulomb explosion. The mechanism of Coulomb explosion is deduced from the distinct charge-dependent kinetic energies of the emitted ions.

However, this Coulomb explosion is not observed in metals ablated with low-intensity femtosecond pulses because electrons from the bulk material rebalance the charge instability before Coulomb explosion can occur.

For femtosecond pulses with the typical high intensity, rapid energy transfer from the laser beam 124 to free electrons and from the free electrons to the lattice leads to local temperatures well above the melting and boiling points, regardless of whether the material is a non-metal or a metal. This produces a superheated solid state over a thickness of several tens of nanometers and higher, and results in a phase change explosion that evaporates the material in the superheated solid state. This is immediately followed by a rapid thermal relaxation that forms a shock wave causing fragmentation from the resulting tensile stress. Thus, ablation with high-intensity femtosecond pulses often creates melted droplets and solid fragments. Because the laser pulse is too short to interact with the evaporating material and any droplets or fragments, the droplets and fragments do not disintegrate and remain part of the plasma plume 122.

Thus, there are significant changes as the duration of laser pulses in laser beam 124 shortens from a nanosecond duration to a femtosecond duration. The plasma plume 122 generated from a nanosecond pulse is mostly of ions of individual atoms, but the plasma plume 122 generated femtosecond pulse often includes a significant fraction of molecular clusters, which can serve as nucleation centers for nanoparticles.

In one embodiment, the source 110 includes a cavity 113 with a wall having an orifice 114 for emitting the plasma jet 112 of the reactive gas. An electrode 115 inside the cavity 113 generates a radiofrequency discharge between the electrode 115 and the wall of the cavity 113. The radiofrequency discharge transitions the reactive gas from a gaseous state to a plasma state for the plasma jet 112. The strength of the radiofrequency discharge is adjusted to change the reactivity of the plasma jet 112. For example, a weaker radiofrequency discharge produces more excited species than ionized species, and a stronger radiofrequency discharge produces more ionized species than excited species.

The source 110 further includes a reservoir 116 for storing a first gas of the reactive gas, and another gas reservoir 117 for storing a second gas of the reactive gas. For example, reservoir 116 stores oxygen and reservoir 117 stores nitrogen, each in a compressed gaseous state. The gases stored in the reservoirs 116 and 117 need not be elemental species. For example, the perovskite thin film AB(ON)₃ is deposited from reservoir 116 storing the species nitrogen dioxide NO₂ and reservoir 117 storing the species nitrous oxide N₂O, because using these gases instead of oxygen O₂ and nitrogen N₂ increases the prevalence of desirable species, such as ON, ON*, ON+, and ON—, in the plasma jet 112. It will be appreciated that there are more or fewer reservoirs in other embodiments. A metering valve 118 controls a first flow rate of the first gas in the gaseous state from the reservoir 116 into the cavity 113, and controls a second flow rate of the second gas in the gaseous state from the reservoir 117 into the cavity 113.

An analyzer 150 monitors an observed stoichiometry of the film 132 during the laser deposition with the reactive gas. For example, a beam from beam source 152 has grazing incidence on the film 132, and analyzer 150 determines the observed stoichiometry of a surface layer of the film 132 from measurements of the reflection, scattering, and/or diffraction of the beam from the surface layer. The analyzer 150 is coupled to the metering valve 118 for dynamically balancing the first and second flow rates so that a ratio between the first and second gases in the observed stoichiometry of the film matches a predetermined stoichiometry for the film. Thus, for the perovskite thin film AB(ON)₃, when the observed stoichiometry includes less nitrogen than oxygen, the flow rate of nitrogen from the reservoir 117 is increased and/or the flow rate of oxygen from the reservoir 116 is decreased.

Typically, nearly of all of the deposition material from plasma plume 122 becomes deposited in the film 132 on substrate 130. Thus, relative ratios between elements originating from the target 120 sets the stoichiometry ratios between these elements in the film 132 resulting from the chemical reaction between the deposition material from the plasma plume 122 and the reactive gas from the plasma jet 112. However, when a particular element of target 120 is volatile and hence evacuated from vacuum vessel 140 in the exhaust from vacuum pump 142, the composition of target 120 is statically modified to appropriately increase the concentration of this particular element.

In addition to dynamically balancing the gases within plasma jet 112 and, if necessary, statically boosting a particular concentration within the target 120 and hence the plasma plume 122, the ratio of species from the plasma plume 122 and species from the plasma jet 112 needs dynamic balancing too. For the perovskite thin film AB(ON)₃, when the observed stoichiometry of the film 132 indicates oxygen and nitrogen are balanced and metals A and B are balanced, but the observed stoichiometry of the film 132 is AB(ON)_{3-X} with X>0, then the observed stoichiometry is deficient in oxygen and nitrogen. To compensate, the flow rate for the plasma jet 112 is increased and/or a pulse rate of the laser beam 124 is decreased to diminish the plasma plume 122. Alternatively, the backpressure within vacuum vessel 140 is increased to increase the fraction of the reactive gas of the plasma jet 112 incorporated into the growing film 132.

Thus, the analyzer 150 is coupled to the vacuum pump 142 for controlling the backpressure within the vacuum vessel 140. The analyzer 150 is coupled to the metering valve 118 for simultaneously adjusting the first and second flow rates from reservoirs 116 and 117. The analyzer 150 is coupled the laser 125 for controlling a pulse rate of the laser beam 124. The analyzer 150 controls the backpressure, flow rate(s) of the reactive gas, and pulse rate of laser beam 124 so that a ratio between the deposition material from the plasma plume 122 and the reactive gas from the plasma jet 112 within the observed stoichiometry of the film 132 matches the predetermined stoichiometry, such as AB(ON)₃, for the film 132.

In one embodiment, a residual gas analyzer 144 monitors the exhaust from the vacuum pump 142. Under steady state conditions, metering valve 118 measures the incoming flow rate of each reactive gas and the residual gas analyzer 144 measures the outgoing flow rate of each reactive gas. From these measurements, the deposition rate is inferred for each reactive gas. Thus, the residual gas analyzer 144 provides stoichiometry information for the deposited film 132, especially the steady-state ratio between each reactive gas in the film 132. This stoichiometry information supplements, or potentially replaces in a well-characterized manufacturing environment, the real-time layer-by-layer monitoring of the observed stoichiometry by analyzer 150.

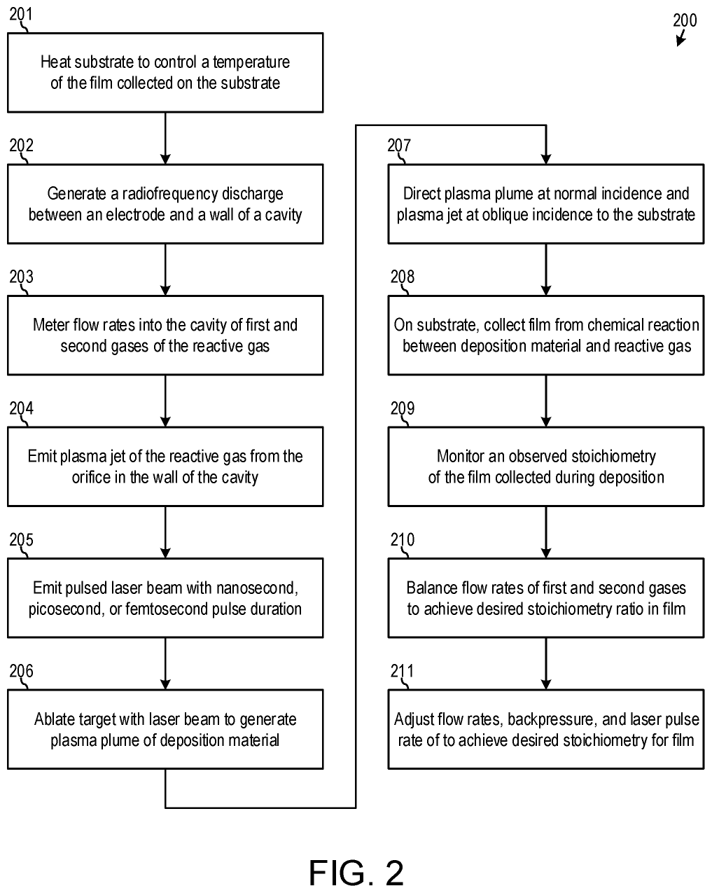

FIG. 2 is a flow diagram of a process 200 for laser deposition with a reactive gas in accordance with an embodiment of the invention.

At step 201, a substrate is heated to control a temperature of the film collected on the substrate.

At step 202, a radiofrequency discharge is generated between an electrode and a wall of a cavity of a source. The wall has an orifice for emitting a plasma jet of the reactive gas. The radiofrequency discharge transitions the reactive gas from a gaseous state to a plasma state for a plasma jet. At step 203, a first gas and a second gas of the reactive gas are metered. This includes controlling a first flow rate into the cavity of the first gas in the gaseous state and controlling a second flow rate into the cavity of the second gas in the gaseous state. At step 204, the plasma jet of the reactive gas is emitted from the orifice of the source.

At step 205, a laser beam is emitted from a laser for generating a plasma plume. The laser beam is a pulsed laser beam with a pulse duration of a nanosecond duration, a picosecond duration, or a femtosecond duration. At step 206, the laser beam ablates a target. This generates a plasma plume of a deposition material from the target. At step 207, the plasma plume is directed toward the substrate at normal incidence and the plasma jet is directed toward the substrate at oblique incidence.

At step 208, a film is collected on the substrate. The film results from a chemical reaction between the deposition material from the plasma plume and the reactive gas from the plasma jet. At step 209, an observed stoichiometry of the film is monitored during the plasma laser deposition with the reactive gas.

At step 210, the first flow rate of the first gas and the second flow rate of the second gas are balanced. This balances the first and second gases within the plasma jet so that a ratio between the first and second gases in the observed stoichiometry of the film matches a predetermined stoichiometry for the film. At step 211, the first and second flow rates are further adjusted and the backpressure and laser pulse rate are adjusted so that a ratio between the deposition material and each of the first and second gases in the observed stoichiometry of the film matches the predetermined stoichiometry for the film. In one embodiment, the first gas is oxygen, the second gas is nitrogen, and the target is composed of metal elements A and B. The film collected on the substrate is a perovskite thin film with the predetermined stoichiometry AB(ON)₃.

From the above description of Laser Deposition with a Reactive Gas, it is manifest that various techniques may be used for implementing the concepts of apparatus 100 and process 200 without departing from the scope of the claims. The described embodiments are to be considered in all respects as illustrative and not restrictive. The method/apparatus disclosed herein may be practiced in the absence of any element that is not specifically claimed and/or disclosed herein. It should also be understood that apparatus 100 or process 200 is not limited to the particular embodiments described herein, but is capable of many embodiments without departing from the scope of the claims.

1. An apparatus for laser deposition with a reactive gas, the apparatus comprising:
a source including a metering valve for metering respective flow rates for a plurality of supply gasses, the source for emitting a plasma jet of the reactive gas, which includes the supply gasses as metered by the metering valve at their respective flow rates;
a laser configured to emit a laser beam that is a pulsed laser beam with a pulse duration of less than a picosecond duration;
a target for generating a plasma plume of a deposition material when the laser beam ablates the target; and
a substrate for collecting a film resulting from a chemical reaction between the deposition material from the plasma plume and the reactive gas from the plasma jet.

2. The apparatus of claim 1, wherein the target and the source are arranged relative to the substrate so that the plasma plume is incident normal to the substrate and the plasma jet is incident obliquely to the substrate.

3. The apparatus of claim 1, further comprising a vacuum vessel enclosing the target and the substrate, the vacuum vessel for containing a first plurality of species of the deposition material from the plasma plume and a second plurality of species of the reactive gas from the plasma jet.

4. The apparatus of claim 3, further comprising:
a window on the vacuum vessel,
wherein the laser is disposed outside the vacuum vessel and arranged to emit the laser beam that is incident on the target via the window for generating the plasma plume of the deposition material when the laser beam ablates the target.

5. The apparatus of claim 4, wherein the laser is configured to emit the laser beam that is the pulsed laser beam with the pulse duration of a femtosecond duration.

6. The apparatus of claim 1, wherein the source further includes:
a cavity with a wall having an orifice for emitting the plasma jet of the reactive gas; and
an electrode inside the cavity for generating a radiofrequency discharge between the electrode and the wall of the cavity, wherein the radiofrequency discharge transitions the supply gasses from a gaseous state to a plasma state for the plasma jet of the reactive gas.

7. The apparatus of claim 6, wherein the source further includes:
a first reservoir for storing a first gas of the supply gasses; and
a second gas reservoir for storing a second gas of the supply gasses,
wherein the metering valve is for controlling a first flow rate of the first gas in the gaseous state from the first reservoir into the cavity and for controlling a second flow rate of the second gas in the gaseous state from the second reservoir into the cavity.

8. The apparatus of claim 7, wherein the first gas stored in the first reservoir is oxygen and the second gas stored in the second reservoir is nitrogen.

9. The apparatus of claim 7, further comprising:
an analyzer for monitoring an observed stoichiometry of the film during the laser deposition with the reactive gas, which includes the first and second gases, wherein the analyzer is coupled to the metering valve for balancing the first and second flow rates so that a ratio between the first and second gases in the observed stoichiometry of the film matches a predetermined stoichiometry for the film.

10. The apparatus of claim 9, further comprising:
a vacuum vessel enclosing the substrate and the target, the vacuum vessel for containing the deposition material from the plasma plume and the first and second gases of the reactive gas from the plasma jet; and
a vacuum pump for evacuating the vacuum vessel to a backpressure,
wherein the analyzer is coupled to the vacuum pump for controlling the backpressure within the vacuum vessel, coupled to the metering valve for adjusting the first and second flow rates further, and coupled to a laser for controlling a pulse rate of the laser beam, so that a ratio between the deposition material and each of the first and second gases in the observed stoichiometry of the film matches the predetermined stoichiometry for the film.

11. The apparatus of claim 10, further comprising the film collected on the substrate, wherein the first gas is oxygen, the second gas is nitrogen, the target is composed of metal elements A and B, and the film collected on the substrate is a perovskite thin film with the predetermined stoichiometry AB(ON)₃.

12. The apparatus of claim 1, further comprising:
an analyzer for monitoring an observed stoichiometry of the film during the laser deposition with the reactive gas, which includes a first gas and a second gas of the supply gasses,
wherein the analyzer is arranged to balance a first flow rate of the first gas and a second flow rate of the second gas within the plasma jet so that a ratio between the first and second gases in the observed stoichiometry of the film matches a predetermined stoichiometry for the film, and
wherein the analyzer is arranged to adjust the first and second flow rates further so that a ratio between the deposition material and each of the first and second gases in the observed stoichiometry of the film matches the predetermined stoichiometry for the film.

13. The apparatus of claim 12, wherein the source further includes:
a cavity with a wall having an orifice for emitting the plasma jet of the reactive gas, which includes the first and second gases;
an electrode inside the cavity for generating a radiofrequency discharge between the electrode and the wall of the cavity, wherein the radiofrequency discharge transitions the the first and second gasses from a gaseous state to a plasma state for the plasma jet of the reactive gas;
a first reservoir for storing the first gas of the supply gasses; and
a second gas reservoir for storing the second gas of the supply gasses,
wherein the metering valve is for controlling the first flow rate of the first gas in the gaseous state from the first reservoir into the cavity and for controlling the second flow rate of the second gas in the gaseous state from the second reservoir into the cavity.

14. The apparatus of claim 1, wherein the reactive gas includes oxygen and nitrogen, the target is composed of metal elements A and B, and the film collected on the substrate is a perovskite thin film with a predetermined stoichiometry AB(ON)₃.

15. The apparatus of claim 1, further comprising:
a heater for heating the substrate; and
a temperature controller for monitoring a temperature of the substrate and for controlling the heater so that the temperature of the film matches a predetermined temperature.

16. A method for the laser deposition with the reactive gas in the apparatus of claim 1, the method comprising:
emitting the plasma jet of the reactive gas from an orifice of the source;
ablating the target with the laser beam, wherein the ablating generates the plasma plume of the deposition material from the target; and
collecting the film on the substrate, the film resulting from the chemical reaction between the deposition material from the plasma plume and the reactive gas from the plasma jet.

17. The method of claim 16, further comprising:
heating the substrate to control a temperature of the film collected on the substrate;
generating a radiofrequency discharge between an electrode and a wall of a cavity of the source, the wall having the orifice for emitting the plasma jet of the reactive gas, wherein the radiofrequency discharge transitions the supply gasses from a gaseous state to a plasma state for the plasma jet of the reactive gas;
metering a first gas and a second gas of the supply gasses, including controlling a first flow rate into the cavity of the first gas in the gaseous state and controlling a second flow rate into the cavity of the second gas in the gaseous state;
emitting the laser beam from the laser for generating the plasma plume, wherein the laser beam is the pulsed laser beam with the pulse duration of less than the picosecond duration; and
directing the plasma plume toward the substrate at normal incidence and directing the plasma jet toward the substrate at oblique incidence.

18. The method of claim 17, further comprising:
monitoring an observed stoichiometry of the film during the laser deposition with the reactive gas;
balancing the first flow rate of the first gas and the second flow rate of the second gas within the plasma jet so that a ratio between the first and second gases in the observed stoichiometry of the film matches a predetermined stoichiometry for the film; and
further adjusting the first and second flow rates so that a ratio between the deposition material and each of the first and second gases in the observed stoichiometry of the film matches the predetermined stoichiometry for the film.

19. The method of claim 18, wherein the first gas is oxygen, the second gas is nitrogen, the target is composed of metal elements A and B, and the film collected on the substrate is a perovskite thin film with the predetermined stoichiometry AB(ON)₃.

20. A system for laser deposition with a reactive gas, the system comprising:
means for emitting a plasma jet of the reactive gas metered from an orifice of a source;
means for ablating a target with a laser beam to generate a plasma plume of a deposition material from the target, wherein the laser beam is a pulsed laser beam with a pulse duration of less than a picosecond duration;
means for collecting a film, the film resulting from a chemical reaction between the deposition material from the plasma plume and the reactive gas from the plasma jet.
